(19) United States
(12) Patent Application Publication
(10) Pub. No.: US 2026/0271266 A1
(43) Pub. Date: Sep. 10, 2026

(54) MEMORY DEVICE AND MANUFACTURING METHOD THEREOF

(71) Applicant: SK hynix Inc., Gyeonggi-do (KR)

(72) Inventor: Heon Yong CHANG, Gyeonggi-do (KR)

(21) Appl. No.: 19/256,164

(22) Filed: Jul. 1, 2025

(30) Foreign Application Priority Data
Mar. 4, 2025 (KR) 10-2025-0027332

(51) Int. Cl. H10B 12/00

(52) U.S. Cl. CPC H10B 12/315; H10B 12/033; H10B 12/50

(57) ABSTRACT

According to embodiments of the present disclosure, a memory device may include a landing pad disposed on the substrate and located in the cell region, a lower electrode in contact with an upper surface of the landing pad, an upper electrode on the lower electrode, a dielectric layer between the lower electrode and the upper electrode, a conductive layer located in the peripheral region and disposed in the same layer as the landing pad, a first contact structure including a first contact plug portion in contact with an upper surface of the conductive layer, and a first contact wiring portion that extends continuously from the first contact plug portion with a width greater than a width of the first contact plug portion, and a first wiring layer disposed on the first contact structure and having a same width as the first contact wiring portion.

The present application claims priority under 35 U.S.C. 119(a) to Korean patent application number 10-2025-0027332 filed on March 4, 2025, which is incorporated herein by reference in its entirety.

### BACKGROUND

### 1. Technical Field

Embodiments of the present disclosure relate to a memory device and a method for manufacturing the same.

### 2. Related Art

Memory devices have been recognized as key components in the electronics industry particularly because of characteristics such as miniaturization, multifunctionality, and/or low manufacturing costs. As the electronics industry continues to advance, memory devices are becoming increasingly highly integrated. To achieve high integration of memory devices, the line width of interconnections included in the memory device is gradually decreasing, thereby increasing the complexity of the manufacturing process.

Various structures having a high aspect ratio may be included in a memory device for electrical connections. As memory devices become more highly integrated, the difficulty of forming structures with a high aspect ratio also increases.

### SUMMARY

According to embodiments of the present disclosure, a memory device and a method for manufacturing the same may be provided to prevent process defects that may occur when forming structures having a high aspect ratio.

The objects of the embodiments of the present disclosure are not limited to those described in this specification, and other objects not explicitly mentioned will be clearly understood by those skilled in the art from the following description.

According to embodiments of the present disclosure, a memory device may comprise a substrate including a cell region and a peripheral region around the cell region, a landing pad disposed on the substrate and located in the cell region, a lower electrode in contact with an upper surface of the landing pad, an upper electrode on the lower electrode, a dielectric layer between the lower electrode and the upper electrode, a conductive layer located in the peripheral region and disposed in the same layer as the landing pad, a first contact structure including a first contact plug portion in contact with an upper surface of the conductive layer, and a first contact wiring portion that extends continuously from the first contact plug portion with a width greater than a width of the first contact plug portion, and a first wiring layer disposed on the first contact structure and having a same width as the first contact wiring portion.

According to embodiments of the present disclosure, a memory device may include a substrate including a cell region and a peripheral region around the cell region, a landing pad disposed on the substrate and located in the cell region, a lower electrode in contact with the landing pad, an upper electrode on the lower electrode, a dielectric layer between the lower electrode and the upper electrode, a conductive layer located in the peripheral region and disposed in the same layer as the landing pad, a first contact structure including a first contact plug portion in contact with an upper surface of the conductive layer and a first contact wiring portion that extends continuously from the first contact plug portion, a first insulating layer surrounding the first contact plug portion, a second insulating layer disposed on the first insulating layer and in contact with a side surface of the first contact wiring portion, and a first wiring layer disposed on the first contact structure and in contact with a side surface of the second insulating layer.

According to embodiments of the present disclosure, a method for manufacturing a memory device may include forming a first insulating layer on an upper electrode of the memory device, the memory device including a lower electrode, the upper electrode on the lower electrode, and a dielectric layer between the lower electrode and the upper electrode, forming a second insulating layer on the first insulating layer, forming a via hole through the first insulating layer and the second insulating layer, forming a trench in the second insulating layer at a region overlapping the via hole, the trench having a width greater than a width of the via hole, filling a conductive material in the via hole and the trench, removing a portion of the conductive material to form a contact structure, an upper surface of which is spaced apart from a lower surface of the trench, and forming a wiring layer on the contact structure, an upper surface of the wiring layer being coplanar with an upper surface of the second insulating layer.

According to embodiments of the present disclosure, a memory device and a method for manufacturing the same may be provided to prevent process defects that may occur when forming structures having a high aspect ratio.

The effects of the embodiments of the present disclosure are not limited to those mentioned above, and other effects not explicitly described will be clearly understood by those skilled in the art from the descriptions in the claims.

### BRIEF DESCRIPTION OF THE DRAWINGS

The present disclosure will be more fully understood from the following detailed description and the accompanying drawings. The detailed description and the accompanying drawings are provided for illustrative purposes only and do not limit the scope of the present disclosure.

FIG. 1 is a diagram illustrating an example of a planar structure of a memory device according to embodiments of the present disclosure.

FIG. 2 is a diagram illustrating an example of a cross-sectional structure taken along line I-I' of FIG. 1 according to an embodiment of the present disclosure.

FIG. 3 is an enlarged view of region 10 of FIG. 2 according to an embodiment of the present disclosure.

FIG. 4 is a diagram illustrating another example of a planar structure of a memory device according to embodiments of the present disclosure.

FIGS. 5 to FIG. 15 are diagrams illustrating an example of a method for manufacturing a memory device according to embodiments of the present disclosure.

### DETAILED DESCRIPTION

Embodiments of the present disclosure are described in detail with reference to the accompanying drawings. In assigning reference numerals to components in each drawing, identical components may be assigned the same reference numerals as much as possible, even when shown in different drawings. Additionally, in describing the present disclosure, if specific descriptions of related known structures or functions are deemed to obscure the subject matter of the present disclosure, such detailed descriptions may be omitted. As used herein, terms such as "comprises" or similar expressions may permit the inclusion of additional elements unless terms like "only" are explicitly used. When a component is expressed in the singular form, it may be interpreted to include the plural form unless explicitly stated otherwise.

Additionally, in describing the components of the present disclosure, terms such as "first," "second," and the like may be used. These terms are merely used to distinguish one component from another, and do not limit the nature, order, sequence, or number of the components.

Regarding the description of the positional relationships between components, when two or more components are described as being "connected," it should be understood that they may be directly "connected" or may have an intervening component. Here, the intervening component may be included in one or more of the two or more components that are "connected" to each other.

Regarding the temporal or sequential relationships of components, operation methods, or fabrication methods, when terms indicating a chronological order or sequential flow are used, unless explicitly stated with terms like "immediately" or "directly," non-continuous cases may also be included.

Regarding mentions of numerical values or corresponding information (e.g., level) related to particular components, unless explicitly stated otherwise, such numerical value or information may be interpreted to include tolerances that may arise due to various factors (e.g., process variations, internal or external impacts, or noise).

Hereinafter, various embodiments of the present disclosure will be described in detail with reference to accompanying drawings.

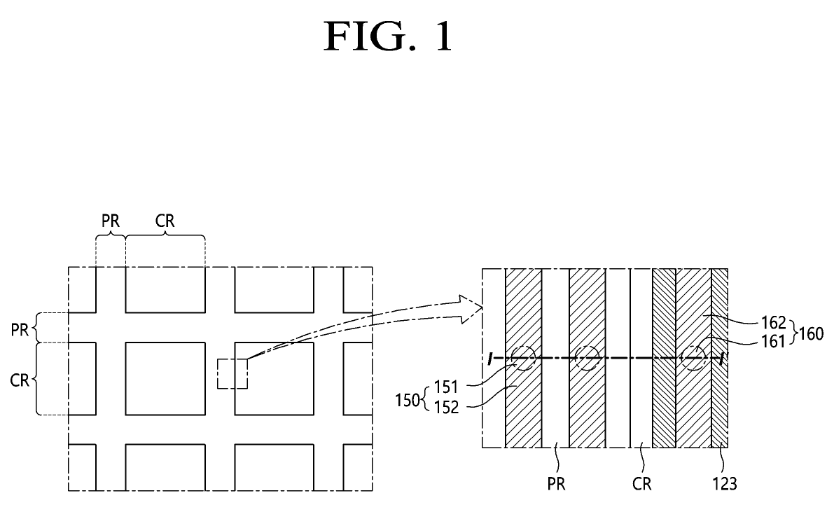

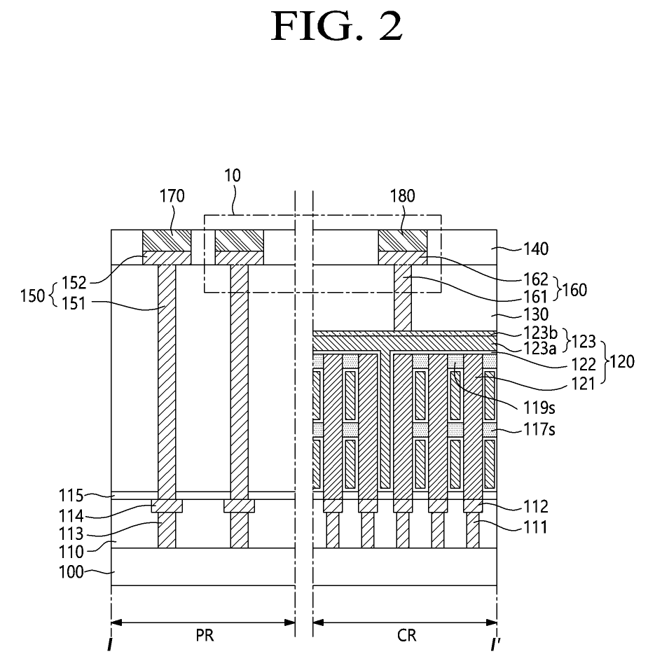

FIG. 1 is a diagram illustrating an example of a planar structure of a memory device according to embodiments of the present disclosure. FIG. 2 is a diagram illustrating an example of a cross-sectional structure taken along line I-I' of FIG. 1.

Referring to FIGS. 1 and FIG. 2, the memory device may include a substrate 100, an interlayer insulating layer 110, a storage node contact 111, a landing pad 112, a first contact 113, a conductive layer 114, an etch stop layer 115, a capacitor 120, a first support 117s, a second support 119s, a first insulating layer 130, a second insulating layer 140, a first contact structure 150, a second contact structure 160, a first wiring layer 170, and a second wiring layer 180.

The capacitor 120 includes a lower electrode 121, a dielectric layer 122, and an upper electrode 123. The first contact structure 150 includes a first contact plug portion 151 and a first contact wiring portion 152. The second contact structure 160 includes a second contact plug portion 161 and a second contact wiring portion 162.

The substrate 100 may include a cell region CR and a peripheral region PR. The cell region CR may be a region in which memory cells included in the memory device are arranged. The peripheral region PR may be a region in which peripheral circuits for delivering various signals and voltages to the memory cells are arranged. The peripheral region PR is disposed around the cell region CR. In some embodiments, the peripheral region PR may surround the cell region CR.

The substrate 100 may include a semiconductor substrate such as a silicon wafer or a silicon-on-insulator (SOI) wafer. The substrate 100 may include a group III-V semiconductor substrate, such as a compound semiconductor substrate such as gallium arsenide (GaAs). The substrate 100 may include monocrystalline silicon, polysilicon, amorphous silicon, monocrystalline silicon germanium, polycrystalline silicon germanium, carbon-doped silicon, or combinations thereof.

An interlayer insulating layer 110 is disposed on the substrate 100. The interlayer insulating layer 110 is illustrated as a single layer but is not limited thereto and may include two or more multiple layers. The interlayer insulating layer 110 may include silicon oxide, silicon nitride, silicon oxynitride, low-k dielectrics, high-k dielectrics, or combinations thereof.

In the cell region CR, a storage node contact 111 and a landing pad 112 are disposed in the interlayer insulating layer 110. The storage node contact 111 may pass through the interlayer insulating layer 110 and contact the upper surface of the substrate 100. The landing pad 112 may be in contact with the storage node contact 111. A bit line (not shown) may be further disposed in the interlayer insulating layer 110. For example, the bit line may be disposed between the storage node contacts 111. A word line (not shown) may be further disposed in the substrate 100. The storage node contact 111 and the landing pad 112 may include a conductive material such as a metal, a metal oxide, a metal nitride, a metal silicide, polysilicon, conductive carbon, or combinations thereof.

In the peripheral region PR, a first contact 113 and a conductive layer 114 are disposed in the interlayer insulating layer 110. The first contact 113 may pass through the interlayer insulating layer 110 and be in contact with the upper surface of the substrate 100. The conductive layer 114 may be in contact with the upper surface of the first contact 113. In some embodiments, the first contact 113 may be in contact with a source region or a drain region of a transistor (not shown) disposed in the substrate 100. In some embodiments, the conductive layer 114 may be disposed in the same layer as the landing pad 112. In some embodiments, the upper surface of the conductive layer 114 may be substantially coplanar with the upper surface of the landing pad 112. The first contact 113 and the conductive layer 114 may include a conductive material such as a metal, a metal oxide, a metal nitride, a metal silicide, polysilicon, conductive carbon, or combinations thereof.

An etch stop layer 115 may be disposed on the interlayer insulating layer 110, the landing pad 112, and the conductive layer 114. The etch stop layer 115 may include silicon nitride (SiN), silicon oxynitride (SiON), silicon carbonitride (SiCN), silicon oxycarbonitride (SiOCN), or combinations thereof.

In the cell region CR, a lower electrode 121 is disposed on the landing pad 112. The lower electrode 121 may pass through the etch stop layer 115 and contact the upper surface of the landing pad 112. The lower electrode 121 may include titanium (Ti), tantalum (Ta), titanium nitride (TiN), tantalum nitride (TaN), titanium oxide (TiO), tantalum oxide (TaO), titanium oxynitride (TiON), tantalum oxynitride (TaON), or combinations thereof.

A first support 117s and a second support 119s may be disposed on the side surface of the lower electrode 121. The first support 117s and the second support 119s may surround the side surface of the lower electrode 121. The first support 117s and the second support 119s may include SiN, SiON, SiCN, SiOCN, or combinations thereof.

A dielectric layer 122 is disposed on the lower electrode 121, the first support 117s, and the second support 119s. The dielectric layer 122 may cover the surfaces of the lower electrode 121, the first support 117s, and the second support 119s. An upper electrode 123 is disposed on the dielectric layer 122. The upper electrode 123 may include a first upper electrode 123a and a second upper electrode 123b disposed on the first upper electrode 123a. The dielectric layer 122 may include silicon oxide, silicon nitride, silicon oxynitride, hafnium oxide (HfO₂), zirconium oxide (ZrO₂), aluminum oxide (Al₂O₃), titanium oxide (TiO₂), tantalum oxide (Ta₂O₅), niobium oxide (Nb₂O₅), strontium titanium oxide (SrTiO₃), ZAZ (ZrO₂/Al₂O₃/ZrO₂) stack, TiO₂/ZrO₂/Al₂O₃/ZrO₂ stack, TiO₂/HfO₂/Al₂O₃/HfO₂ stack, Ta₂O₅/ZrO₂/Al₂O₃/ZrO₂ stack, Ta₂O₅/HfO₂/Al₂O₃/HfO₂ stack, or combinations thereof. In some embodiments, the first upper electrode 123a may include silicon germanium (SiGe), and the second upper electrode 123b may include tungsten nitride (WN).

A first insulating layer 130 is disposed on the upper electrode 123 and the etch stop layer 115. A second insulating layer 140 is disposed on the first insulating layer 130. The first insulating layer 130 and the second insulating layer 140 may include silicon oxide, silicon nitride, silicon oxynitride, low-k dielectrics, high-k dielectrics, or combinations thereof. In some embodiments, the first insulating layer 130 and the second insulating layer 140 may include an oxide.

In the peripheral region PR, a first contact structure 150 is disposed on the conductive layer 114. The first contact structure 150 may pass through the first insulating layer 130, the second insulating layer 140, and the etch stop layer 115 and be in contact with the upper surface of the conductive layer 114. The first contact structure 150 includes a first contact plug portion 151 and a first contact wiring portion 152.

The first contact plug portion 151 may be in contact with an upper surface of the conductive layer 114. The distance from the upper surface of the first contact plug portion 151 to the substrate 100 may be greater than the distance from the upper surface of the upper electrode 123 to the substrate 100. Referring to FIG. 1, in some embodiments, the first contact plug portion 151 may have a columnar shape with a uniform cross-sectional width. Although FIG. 1 illustrates the first contact plug portion 151 with a circular cross-section, the cross-sectional shape of the first contact plug portion 151 is not limited thereto. A first contact wiring portion 152 may be disposed on the first contact plug portion 151. The first contact wiring portion 152 is continuously extended (for example, that extends continuously) from the first contact plug portion 151.

The first contact plug portion 151 and the first contact wiring portion 152 may include a conductive material such as a metal, a metal oxide, a metal nitride, a metal silicide, polysilicon, conductive carbon, or combinations thereof. In some embodiments, the first contact plug portion 151 and the first contact wiring portion 152 may include W, Ti, TiN, TiO, TiON, or combinations thereof.

A first wiring layer 170 is disposed on the first contact wiring portion 152. The first wiring layer 170 may pass through the second insulating layer 140 and be in contact with the first contact wiring portion 152. The first wiring layer 170 may include a conductive material such as a metal, a metal oxide, a metal nitride, a metal silicide, polysilicon, conductive carbon, or combinations thereof. In some embodiments, the first wiring layer 170 may include copper (Cu), Ta, TaN, TaO, TaON, or combinations thereof.

A second contact structure 160 is disposed on the upper electrode 123 in the cell region CR. The second contact structure 160 may pass through the first insulating layer 130 and be in contact with an upper surface of the upper electrode 123. The second contact structure 160 includes a second contact plug portion 161 and a second contact wiring portion 162.

The second contact plug portion 161 may be in contact with an upper surface of the upper electrode 123. The distance from the upper surface of the second contact plug portion 161 to the upper electrode 123 may be smaller than the distance from the upper surface of the first contact plug portion 151 to the substrate 100. Referring to FIG. 1, in some embodiments, the second contact plug portion 161 may have a columnar shape with a uniform cross-sectional width. Although FIG. 1 illustrates the second contact plug portion 161 with a circular cross-section, the cross-sectional shape of the second contact plug portion 161 is not limited thereto. A second contact wiring portion 162 may be disposed on the second contact plug portion 161. The second contact wiring portion 162 is continuously extended from the second contact plug portion 161.

The second contact plug portion 161 and the second contact wiring portion 162 may include a conductive material such as a metal, a metal oxide, a metal nitride, a metal silicide, polysilicon, conductive carbon, or combinations thereof. In some embodiments, the second contact plug portion 161 and the second contact wiring portion 162 may include W, Ti, TiN, TiO, TiON, or combinations thereof.

A second wiring layer 180 is disposed on the second contact wiring portion 162. The second wiring layer 180 may pass through the second insulating layer 140 and be in contact with the first contact wiring portion 152. The second wiring layer 180 may include a conductive material such as a metal, a metal oxide, a metal nitride, a metal silicide, polysilicon, conductive carbon, or combinations thereof. In some embodiments, the second wiring layer 180 may include Cu, Ta, TaN, TaO, TaON, or combinations thereof.

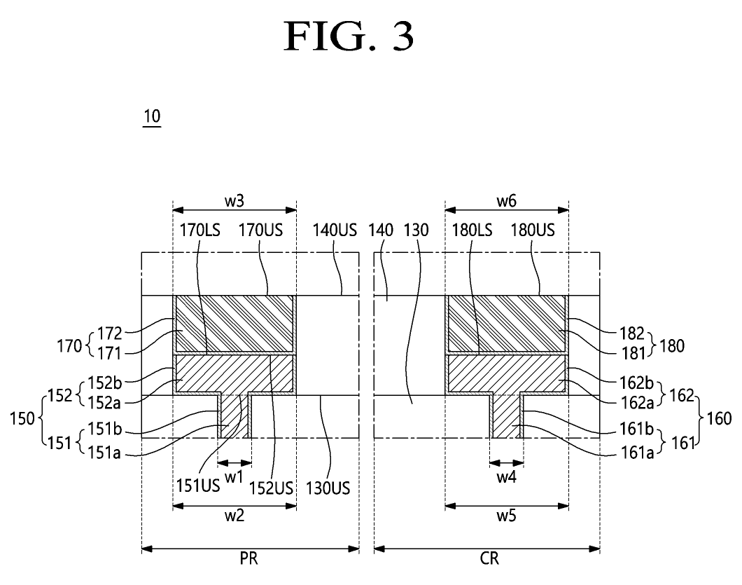

FIG. 3 is an enlarged view of region 10 of FIG. 2.

Referring to FIGS. 2 and FIG. 3, the first contact plug portion 151 may include a first contact plug barrier portion 151b and a first contact plug conductive portion 151a. The first contact plug barrier portion 151b may surround a side surface of the first contact plug conductive portion 151a. The first contact plug barrier portion 151b may include Ti, TiN, TiO, TiON, or combinations thereof. The first contact plug conductive portion 151a may include tungsten.

The first contact wiring portion 152 may include a first contact wiring barrier portion 152b and a first contact wiring conductive portion 152a. The first contact wiring barrier portion 152b is continuously extending from the first contact plug barrier portion 151b. The first contact wiring barrier portion 152b may include the same material as the first contact plug barrier portion 151b. The first contact wiring conductive portion 152a is continuously extended from the first contact plug conductive portion 151a. The first contact wiring conductive portion 152a may include the same material as the first contact plug conductive portion 151a.

The first insulating layer 130 may surround a side surface of the first contact plug portion 151. An upper surface 130US of the first insulating layer 130 may be substantially coplanar with an upper surface 151US of the first contact plug portion 151. The first insulating layer 130 may be positioned below the first contact wiring portion 152. The first insulating layer 130 may be in contact with a lower surface of the first contact wiring barrier portion 152b.

A first wiring layer 170 is disposed on the first contact wiring portion 152. The first wiring layer 170 may include a first wiring barrier portion 172 and a first wiring conductive portion 171. The first wiring barrier portion 172 may surround a side surface and a lower surface of the first wiring conductive portion 171. A lower surface 170LS of the first wiring layer 170 may be in contact with an upper surface 152US of the first contact wiring portion 152. For example, a lower surface of the first wiring barrier portion 172 may be in contact with the upper surface 152US of the first contact wiring portion 152. The first wiring barrier portion 172 may be spaced apart from the upper surface 151US of the first contact plug portion 151. The first wiring barrier portion 172 may include Ta, TaN, TaO, TaON, or combinations thereof. The first wiring conductive portion 171 may include copper.

A second insulating layer 140 may be disposed on the first insulating layer 130. The second insulating layer 140 may be in contact with a side surface of the first contact wiring portion 152 and a side surface of the first wiring layer 170. An upper surface 140US of the second insulating layer 140 may be substantially coplanar with an upper surface 170US of the first wiring layer 170.

In some embodiments, a width w1 of the first contact plug portion 151 may be smaller than a width w2 of the first contact wiring portion 152. In some embodiments, a width w3 of the first wiring layer 170 may be substantially the same as the width w2 of the first contact wiring portion 152.

The second contact plug portion 161 may include a second contact plug barrier portion 161b and a second contact plug conductive portion 161a. The second contact plug barrier portion 161b may surround a side surface of the second contact plug conductive portion 161a. The second contact plug barrier portion 161b may include Ti, TiN, TiO, TiON, or combinations thereof. The second contact plug conductive portion 161a may include tungsten.

The second contact wiring portion 162 may include a second contact wiring barrier portion 162b and a second contact wiring conductive portion 162a. The second contact wiring barrier portion 162b is continuously extended from the second contact plug barrier portion 161b. The second contact wiring barrier portion 162b may include the same material as the second contact plug barrier portion 161b. The second contact wiring conductive portion 162a is continuously extended from the second contact plug conductive portion 161a. The second contact wiring conductive portion 162a may include the same material as the second contact plug conductive portion 161a. An upper surface of the second contact wiring portion 162 may be positioned at substantially the same height as an upper surface 152US of the first contact wiring portion 152.

The first insulating layer 130 may surround a side surface of the second contact plug portion 161. An upper surface 130US of the first insulating layer 130 may be substantially coplanar with an upper surface of the second contact plug portion 161. The first insulating layer 130 may be positioned below the second contact wiring portion 162. The first insulating layer 130 may be in contact with a lower surface of the second contact wiring barrier portion 162b.

A second wiring layer 180 is disposed on the second contact wiring portion 162. The second wiring layer 180 may include a second wiring barrier portion 182 and a second wiring conductive portion 181. The second wiring barrier portion 182 may surround a side surface and a lower surface of the second wiring conductive portion 181. A lower surface 180LS of the second wiring layer 180 may be in contact with an upper surface of the second contact wiring portion 162. For example, a lower surface of the second wiring barrier portion 182 may be in contact with an upper surface of the second contact wiring portion 162. The second wiring barrier portion 182 may be spaced apart from an upper surface of the second contact plug portion 161. An upper surface 180US of the second wiring layer 180 may be substantially coplanar with an upper surface 170US of the first wiring layer 170. The second wiring barrier portion 182 may include Ta, TaN, TaO, TaON, or combinations thereof. The second wiring conductive portion 181 may include copper.

The second insulating layer 140 may be in contact with a side surface of the second contact wiring portion 162 and a side surface of the second wiring layer 180. An upper surface 140US of the second insulating layer 140 may be substantially coplanar with an upper surface 180US of the second wiring layer 180.

In some embodiments, a width w4 of the second contact plug portion 161 may be smaller than a width w5 of the second contact wiring portion 162. In some embodiments, a width w6 of the second wiring layer 180 may be substantially the same as the width w5 of the second contact wiring portion 162.

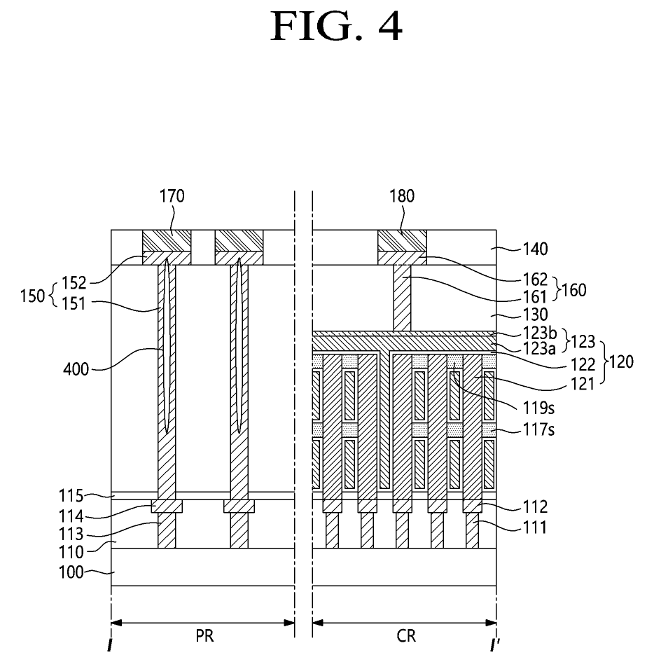

FIG. 4 is a diagram illustrating another example of a planar structure of a memory device according to embodiments of the present disclosure.

Referring to FIG. 4, the memory device may further include a core 400. Among the components included in the memory device shown in FIG. 4, components other than the core 400 may be substantially the same as the components of the memory device described with reference to FIG. 2.

The core 400 may be disposed in the first contact structure 150. In some embodiments, the core 400 may be disposed in the first contact plug portion 151 of the first contact structure 150. In some embodiments, the core 400 may extend from the first contact plug portion 151 to the first contact wiring portion 152. In some embodiments, an uppermost end of the core 400 may be spaced apart from an upper surface of the first contact wiring portion 152. The uppermost end of the core 400 may be positioned between an upper surface of the first contact plug portion 151 and an upper surface of the first contact wiring portion 152.

In some embodiments, in instances in which the core 400 is formed to penetrate the upper surface of the first contact plug portion 151, the first contact wiring portion 152 may be disposed on the first contact plug portion 151. Accordingly, the core 400 may not be exposed above an upper surface of the first contact structure 150.

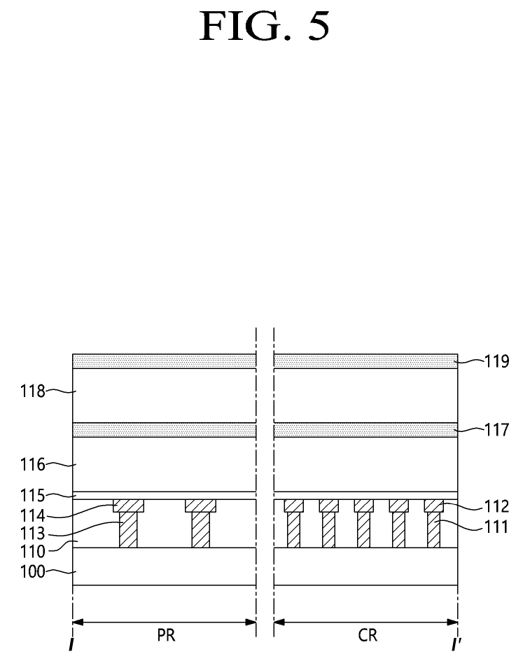

FIGS. 5 to FIG. 15 are diagrams illustrating an example of a method for manufacturing a memory device according to embodiments of the present disclosure.

Referring to FIG. 5, an interlayer insulating layer 110 is formed on the substrate 100. Although not illustrated, word lines may be embedded in the substrate 100. In the cell region CR, a storage node contact 111 and a landing pad 112 are formed in the interlayer insulating layer 110. The storage node contact 111 may pass through the interlayer insulating layer 110 and be in contact with an upper surface of the substrate 100. Although not illustrated, bit lines may be formed between the storage node contacts 111. In the peripheral region PR, a first contact 113 and a conductive layer 114 are formed in the interlayer insulating layer 110. The first contact 113 may pass through the interlayer insulating layer 110 and be in contact with an upper surface of the substrate 100.

An etch stop layer 115 is formed on the interlayer insulating layer 110, the landing pad 112, and the conductive layer 114. In some embodiments, the etch stop layer 115 may protect the substrate and various elements formed on the substrate from an etchant during a subsequent wet etching process.

A first mold layer 116, a first support material layer 117, a second mold layer 118, and a second support material layer 119 are sequentially formed on the etch stop layer 115. The first mold layer 116 and the second mold layer 118 may each include silicon oxide, silicon nitride, silicon oxynitride, low-k dielectrics, high-k dielectrics, or combinations thereof. In some embodiments, the first mold layer 116 and the second mold layer 118 may include borophosphosilicate glass (BPSG).

The first support material layer 117 and the second support material layer 119 may include SiN, SiON, SiCN, SiOCN, or combinations thereof.

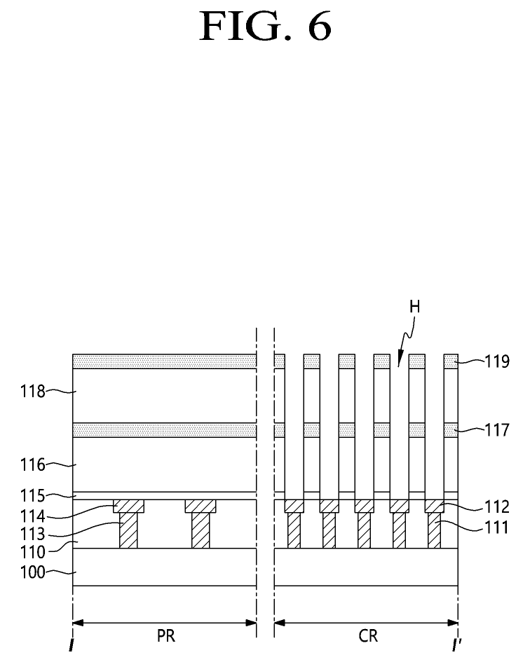

Referring to FIG. 6, at least one hole H may be formed in the cell region CR. The hole H may pass through the second support material layer 119, the second mold layer 118, the first support material layer 117, the first mold layer 116, and the etch stop layer 115, thereby exposing an upper surface of the landing pad 112. The hole H may correspond to one landing pad 112.

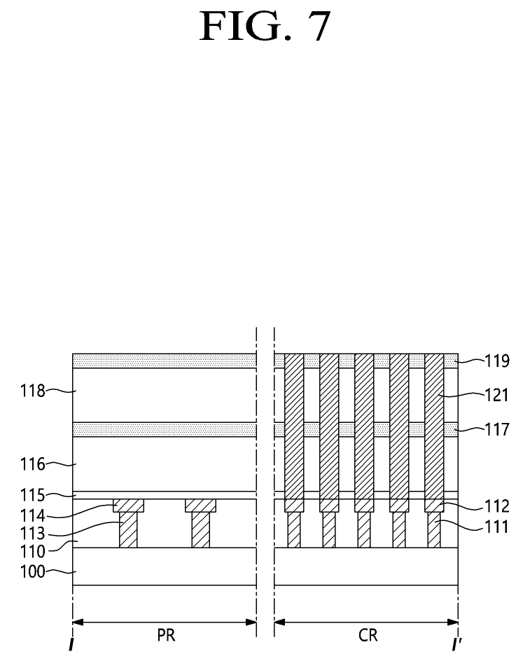

Referring to FIGS. 6 and FIG. 7, a lower electrode 121 is formed in the hole H. In some embodiments, the lower electrode 121 may include TiN. An upper surface of the lower electrode 121 may be substantially coplanar with an upper surface of the second support material layer 119. A lower surface of the lower electrode 121 may be in contact with an upper surface of the landing pad 112. The etch stop layer 115, the first mold layer 116, the first support material layer 117, the second mold layer 118, and the second support material layer 119 may surround a side surface of the lower electrode 121.

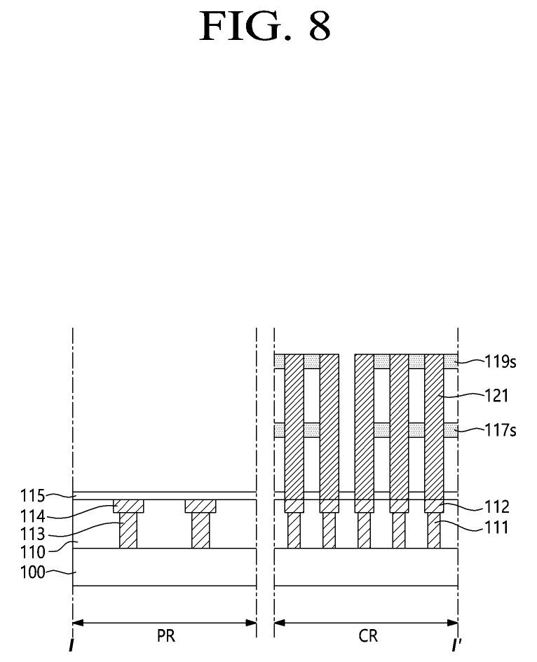

Referring to FIG. 8, at least a portion of the second support material layer 119 located in the cell region CR may be removed. The process of removing the second support material layer 119 may include, for example, a dry etching process. After at least a portion of the second support material layer 119 is removed, the second mold layer 118 may be removed. The process of removing the second mold layer 118 may include, for example, a wet etching process. When the second mold layer 118 is removed, a second support 119s may be formed.

After the second support 119s is formed, at least a portion of the first support material layer 117 may be removed. The process of removing the first support material layer 117 may include, for example, a dry etching process. After at least a portion of the first support material layer 117 is removed, the first mold layer 116 may be removed. The process of removing the first mold layer 116 may include, for example, a wet etching process. When the first mold layer 116 is removed, a first support 117s may be formed.

During the process of removing the first mold layer 116 and the second mold layer 118, the first support material layer 117 and the second support material layer 119 formed in the peripheral region PR may also be removed.

The first support 117s and the second support 119s may surround a side surface of the lower electrode 121. The first support 117s may be spaced apart from the second support 119s. The first support 117s and the second support 119s may each include the same material as the first support material layer 117 and the second support material layer 119, respectively.

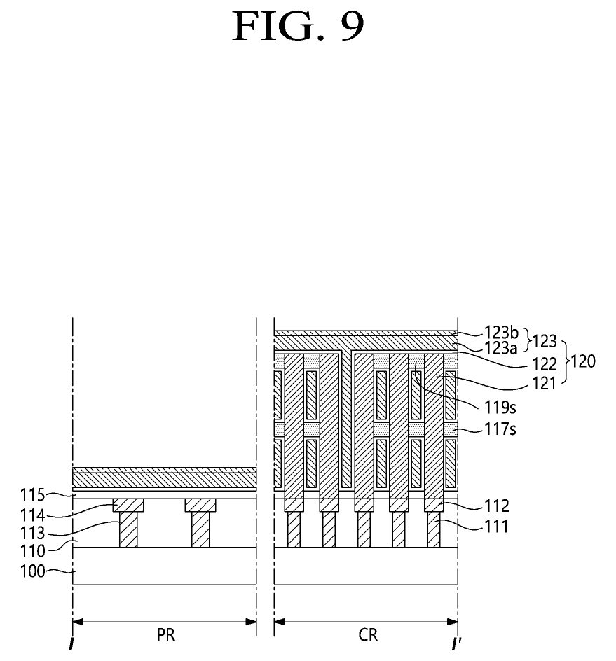

Referring to FIG. 9, a dielectric layer 122 and an upper electrode 123 are formed on the etch stop layer 115, the lower electrode 121, and the second support 119s. The dielectric layer 122 may cover an upper surface of the etch stop layer 115 formed in the peripheral region PR. The dielectric layer 122 may be formed on surfaces of the first support 117s, the second support 119s, the lower electrode 121, and the etch stop layer 115 in the cell region CR. The upper electrode 123 may be formed on the dielectric layer 122. The dielectric layer 122 may be positioned between the lower electrode 121 and the upper electrode 123. The upper electrode 123 may include a first upper electrode 123a and a second upper electrode 123b. The first upper electrode 123a may fill regions between the lower electrodes 121.

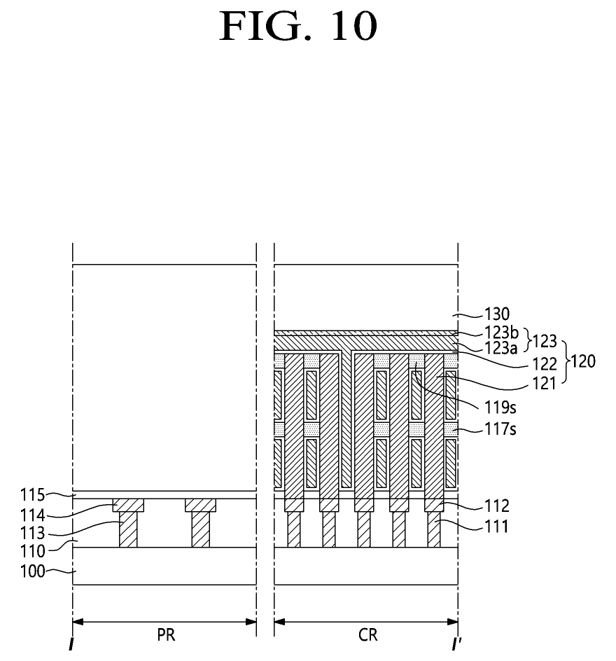

Referring to FIG. 10, a portion of the dielectric layer 122 and the upper electrode 123 may be removed. In some embodiments, portions of the dielectric layer 122 and the upper electrode 123 located in the peripheral region PR may be removed.

A first insulating layer 130 may be formed on the etch stop layer 115 and the upper electrode 123. The first insulating layer 130 may cover an upper surface of the etch stop layer 115 and the upper electrode 123.

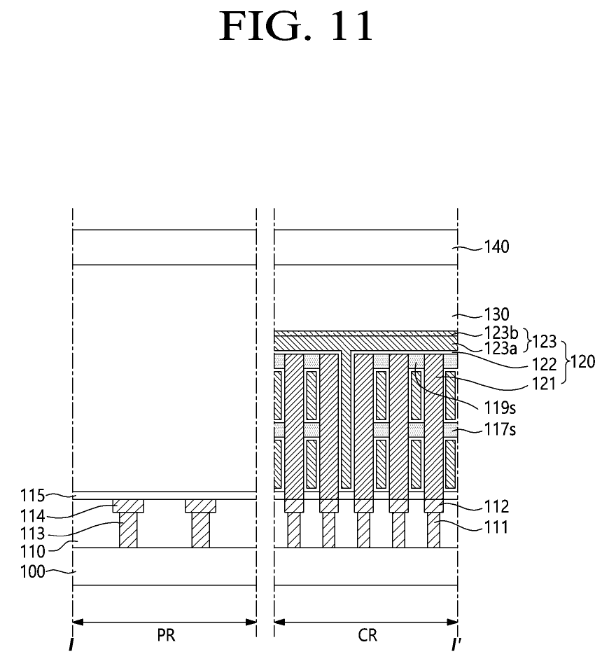

Referring to FIG. 11, a second insulating layer 140 may be formed on the first insulating layer 130. In some embodiments, the first insulating layer 130 and the second insulating layer 140 may include an oxide.

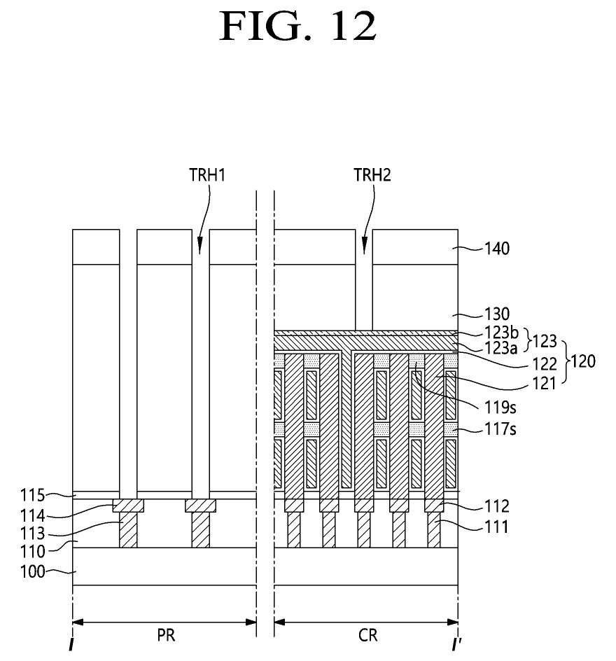

Referring to FIG. 12, a first through-hole TRH1 and a second through-hole TRH2 may be formed to pass through the first insulating layer 130 and the second insulating layer 140. The first through-hole TRH1 may be formed in the peripheral region PR, and the second through-hole TRH2 may be formed in the cell region CR. The first through-hole TRH1 may pass through the first insulating layer 130, the second insulating layer 140, and the etch stop layer 115 to expose an upper surface of the conductive layer 114. The second through-hole TRH2 may pass through the first insulating layer 130 and the second insulating layer 140 to expose an upper surface of the upper electrode 123.

In some embodiments, a length of the first through-hole TRH1 may be greater than a length of the second through-hole TRH2. In some embodiments, a width of the first through-hole TRH1 may be substantially the same as a width of the second through-hole TRH2.

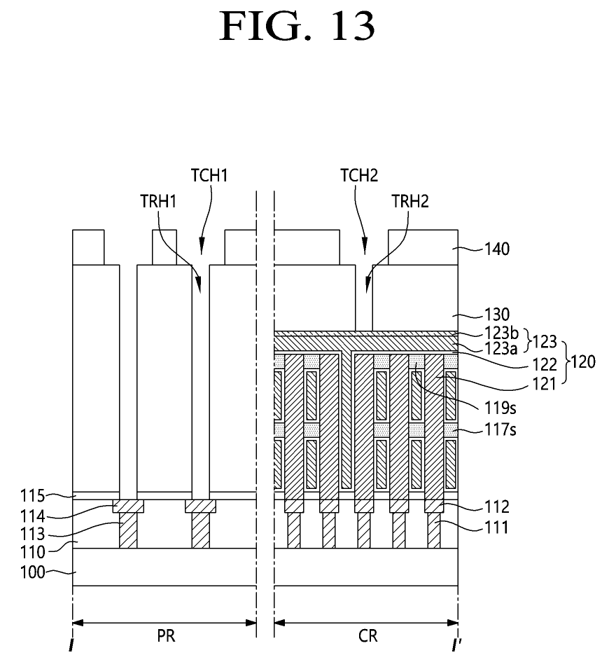

Referring to FIG. 13, a first trench TCH1 and a second trench TCH2 may be formed in the second insulating layer 140. The first trench TCH1 may be formed in a region overlapping the first through-hole TRH1. The second trench TCH2 may be formed in a region overlapping the second through-hole TRH2. A width of the first trench TCH1 may be greater than a width of the first through-hole TRH1. A width of the second trench TCH2 may be greater than a width of the second through-hole TRH2. The process of forming the first trench TCH1 and the second trench TCH2 may include an etching process.

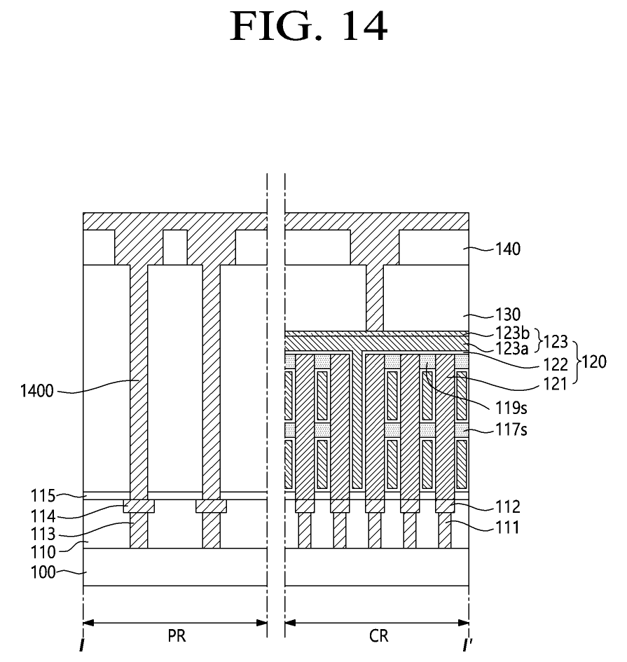

Referring to FIG. 14, a conductive material 1400 may be filled in the first trench TCH1, the first through-hole TRH1, the second trench TCH2, and the second through-hole TRH2. The conductive material 1400 may include W, Ti, TiN, TiO, TiON, or combinations thereof. A distance from an upper surface of the conductive material 1400 to an upper surface of the first insulating layer 130 may be greater than a distance from an upper surface of the second insulating layer 140 to an upper surface of the first insulating layer 130. The conductive material 1400 may cover an upper surface of the second insulating layer 140.

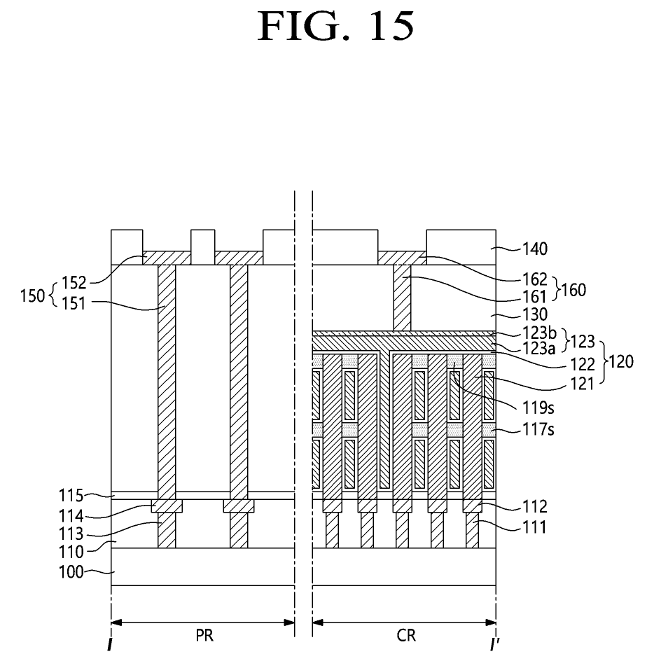

Referring to FIG. 15, at least a portion of the conductive material 1400 may be removed to form a first contact structure 150 and a second contact structure 160. The first contact structure 150 may include a first contact plug portion 151 and a first contact wiring portion 152. The second contact structure 160 may include a second contact plug portion 161 and a second contact wiring portion 162. The first contact plug portion 151, the first contact wiring portion 152, the second contact plug portion 161, and the second contact wiring portion 162 may be formed in the same process step.

The process of forming the first contact structure 150 and the second contact structure 160 may include a chemical mechanical polishing (CMP) process, an etching process, or a combination thereof. An upper surface of the first contact structure 150 and an upper surface of the second contact structure 160 may be positioned between an upper surface of the first insulating layer 130 and an upper surface of the second insulating layer 140. Referring to FIGS. 13 and FIG. 15, an upper surface of the first contact structure 150 may be spaced apart from a lower surface of the first trench TCH1 and a lower surface of the second trench TCH2. An upper surface of the second contact structure 160 may be spaced apart from a lower surface of the first trench TCH1 and a lower surface of the second trench TCH2.

Referring again to FIG. 2, a first wiring layer 170 may be formed on the first contact structure 150, and a second wiring layer 180 may be formed on the second contact structure 160. An upper surface of the first wiring layer 170 may be substantially coplanar with an upper surface of the second insulating layer 140. An upper surface of the second wiring layer 180 may be substantially coplanar with an upper surface of the second insulating layer 140.

According to embodiments of the present disclosure, the first contact structure 150 may include a first contact plug portion 151 and a first contact wiring portion 152 continuously extended from the first contact plug portion 151. A width w2 of the first contact wiring portion 152 may be greater than a width w1 of the first contact plug portion 151. A first wiring layer 170 may be disposed on the first contact structure 150. A width w3 of the first wiring layer 170 may be substantially the same as the width w2 of the first contact wiring portion 152.

According to embodiments of the present disclosure, process defects that occur when forming structures with a high aspect ratio may be prevented.

The first contact plug portion 151 may have a high aspect ratio (for example, one dimension of the first contact plug portion 151 (e.g., the length) may be significantly larger than the other (e.g., the width)). When the first contact plug portion 151 has a high aspect ratio, a core (for example, the core 400 described herein above with respect to FIG. 4) may be formed inside the first contact plug portion 151 during the formation of the first contact plug portion 151 in the first through-hole TRH1. In some embodiments, the core may penetrate the upper surface of the first contact plug portion 151. However, in instances in which the first contact wiring portion 152 is disposed on the first contact plug portion 151, including instances in which the core penetrates the upper surface of the first contact plug portion 151, the core may not penetrate the upper surface of the first contact structure 150. Accordingly, the issue of reduced contact area between the upper surface of the first contact structure 150 and the lower surface of the first wiring layer 170 due to the penetration of the core through the upper surface of the first contact plug portion 151 may be minimized. Thus, process defects caused by increased contact resistance between the first contact structure 150 and the first wiring layer 170 may be prevented.

Although exemplary embodiments of the disclosure have been described for illustrative purposes, those skilled in the art will appreciate that various modifications, additions and substitutions are possible, without departing from the scope and spirit of the disclosure. Therefore, the embodiments disclosed above and in the accompanying drawings should be considered in a descriptive sense only and not for limiting the technological scope. The technological scope of the disclosure is not limited by the embodiments and the accompanying drawings.

What is claimed is:

1. A memory device comprising:
a substrate including a cell region and a peripheral region around the cell region;
a landing pad disposed on the substrate and located in the cell region;
a lower electrode in contact with an upper surface of the landing pad;
an upper electrode on the lower electrode;
a dielectric layer between the lower electrode and the upper electrode;
a conductive layer located in the peripheral region and disposed in the same layer as the landing pad;
a first contact structure including a first contact plug portion in contact with an upper surface of the conductive layer, and a first contact wiring portion that extends continuously from the first contact plug portion with a width greater than a width of the first contact plug portion; and
a first wiring layer disposed on the first contact structure and having a substantially same width as the first contact wiring portion.

2. The memory device according to claim 1, further comprising a first insulating layer disposed on the conductive layer and surrounding the first contact plug portion.

3. The memory device according to claim 2, wherein an upper surface of the first insulating layer is substantially coplanar with an upper surface of the first contact plug portion.

4. The memory device according to claim 2, further comprising a second insulating layer disposed on the first insulating layer,
wherein the second insulating layer is in contact with a side surface of the first contact wiring portion and a side surface of the first wiring layer.

5. The memory device according to claim 4, wherein an upper surface of the second insulating layer is substantially coplanar with an upper surface of the first wiring layer.

6. The memory device according to claim 1, wherein a lower surface of the first wiring layer is in contact with an upper surface of the first contact wiring portion.

7. The memory device according to claim 1, wherein the first wiring layer comprises a first wiring conductive portion and a first wiring barrier portion surrounding a lower surface and a side surface of the first wiring conductive portion and in contact with an upper surface of the first contact wiring portion.

8. The memory device according to claim 7, wherein the first wiring barrier portion is spaced apart from an upper surface of the first contact plug portion.

9. The memory device according to claim 1, further comprising:
a second contact structure including a second contact plug portion in contact with an upper surface of the upper electrode, and a second contact wiring portion continuously extended from the second contact plug portion and having a width greater than a width of the second contact plug portion; and
a second wiring layer disposed on the second contact structure and having a substantially same width as the second contact wiring portion,
wherein an upper surface of the second wiring layer is substantially coplanar with an upper surface of the first wiring layer.

10. The memory device according to claim 9, wherein a lower surface of the second wiring layer is in contact with an upper surface of the second contact wiring portion.

11. The memory device according to claim 1, wherein the first contact structure comprises tungsten, and the first wiring layer comprises copper.

12. A memory device comprising:
a substrate including a cell region and a peripheral region around the cell region;
a landing pad disposed on the substrate and located in the cell region;
a lower electrode in contact with the landing pad;
an upper electrode on the lower electrode;
a dielectric layer between the lower electrode and the upper electrode;
a conductive layer located in the peripheral region and disposed in the same layer as the landing pad;
a first contact structure including a first contact plug portion in contact with an upper surface of the conductive layer and a first contact wiring portion that extends continuously from the first contact plug portion;
a first insulating layer surrounding the first contact plug portion;
a second insulating layer disposed on the first insulating layer and in contact with a side surface of the first contact wiring portion; and
a first wiring layer disposed on the first contact structure and in contact with a side surface of the second insulating layer.

13. The memory device according to claim 12, wherein a width of the first contact wiring portion is greater than a width of the first contact plug portion.

14. The memory device according to claim 12, wherein a width of the first wiring layer is substantially the same as a width of the first contact wiring portion.

15. The memory device according to claim 12, wherein a lower surface of the first wiring layer is in contact with an upper surface of the first contact wiring portion.

16. The memory device according to claim 12, wherein the first wiring layer includes
a first wiring conductive portion and a first wiring barrier portion, wherein the first wiring barrier portion surrounds a lower surface and a side surface of the first wiring conductive portion, and is in contact with an upper surface of the first contact wiring portion.

17. The memory device according to claim 16, wherein the first wiring barrier portion is spaced apart from an upper surface of the first contact plug portion.

18. The memory device according to claim 12, further comprising:
a second contact structure including a second contact plug portion in contact with an upper surface of the upper electrode and a second contact wiring portion continuously extended from the second contact plug portion; and
a second wiring layer disposed on the second contact structure and in contact with a side surface of the second insulating layer,
wherein an upper surface of the second wiring layer is substantially coplanar with an upper surface of the first wiring layer.

19. The memory device according to claim 12, wherein an upper surface of the second insulating layer is substantially coplanar with an upper surface of the second wiring layer.

20. A method of manufacturing a memory device, the method comprising:
forming a first insulating layer on an upper electrode of the memory device, the memory device comprising a lower electrode, the upper electrode on the lower electrode, and a dielectric layer between the lower electrode and the upper electrode;
forming a second insulating layer on the first insulating layer;
forming a via hole through the first insulating layer and the second insulating layer;
forming a trench in the second insulating layer at a region overlapping the via hole, the trench having a width greater than a width of the via hole;
filling a conductive material in the via hole and the trench;
removing a portion of the conductive material to form a contact structure, an upper surface of which is spaced apart from a lower surface of the trench; and
forming a wiring layer on the contact structure, an upper surface of the wiring layer being substantially coplanar with an upper surface of the second insulating layer.
